(19) United States
(12) Patent Application Publication
(10) Pub. No.: US 2008/0174319 A1
(43) Pub. Date: Jul. 24, 2008

(54) Load Board Based Test Circuits

(76) Inventor: Marcellus C. Harper, Kaysville, UT (US)

Correspondence Address: STEVEN L. NICHOLS;RADER, FISHMAN & GRAVER PLLC, 10653 S. RIVER FRONT PARKWAY, SUITE 150, SOUTH JORDAN, UT, 84095, US

(21) Appl. No.: 12/013,252

(22) Filed: Jan. 11, 2008

Related U.S. Application Data
(60) Provisional application No. 60/880,111, filed on Jan. 11, 2007.

(51) Int. Cl. G01R 31/02

(52) U.S. Cl. 324/537

(57) ABSTRACT

A load board based test circuit includes a control module which receives user input over a user interface; a testing interface which makes a connection said load board based test circuit and a device under test; a memory which holds calibration values, test parameters, or test results; and a means for manipulating a test signal.

### RELATED APPLICATIONS

This application claims the benefit under 35 U.S.C. § 119(e) of U.S. Provisional Patent Application No. 60/880,111 filed Jan. 11, 2007 entitled “Test Solutions and Methods for Difficult Case Signals Encountered in Automatic Test Equipment.” The afore mentioned application is incorporated herein by reference in its entirety.

### BACKGROUND

Automatic test equipment (ATE) typically includes at least one device under test (DUT), a load board, and a pin electronics card (PEC). The DUT may be variety of different electronic components including, but not limited to, integrated circuits (ICs), analog pins, universal serial bus (USB) ports, radio frequency (RF) circuits, differentially paired signal circuitry, and digital pins. A typical PEC is used to perform a variety of tests on the DUT. The load board is a circuit board designed to serve as an interface between the PEC and the DUT. During the testing of a DUT it can be desirable to minimize external disturbances to the signal produced or sent to the DUT. For example, the distance, time delays, and various components between PEC and the DUT can create disturbances to signals passed between them.

### BRIEF DESCRIPTION OF THE DRAWINGS

The accompanying drawings illustrate various embodiments of the principles described herein and are a part of the specification. The illustrated embodiments are merely examples and do not limit the scope of the disclosure.

FIG. 1 is an illustrative diagram of chip testing using automatic test equipment, according to principles described herein.

FIG. 2 is an illustrative diagram showing one exemplary embodiment of an analog tester, according to principles described herein.

FIG. 3 is an illustrative diagram of one exemplary front end scaling block for use within an analog tester, according to principles described herein.

FIG. 4 is an illustrative diagram of an exemplary arbitrary waveform generator (AWG), according to principles described herein.

FIG. 5 is an illustrative diagram of one exemplary embodiment of a radio frequency (RF) tester that may be used to test an RF DUT, according to principles described herein.

Throughout the drawings, identical reference numbers designate similar, but not necessarily identical, elements.

### DETAILED DESCRIPTION

In the following description, for purposes of explanation, numerous specific details are set forth in order to provide a thorough understanding of the present systems and methods. It will be apparent, however, to one skilled in the art that the present apparatus, systems and methods may be practiced without these specific details. Reference in the specification to “an embodiment,” “an example” or similar language means that a particular feature, structure, or characteristic described in connection with the embodiment or example is included in at least that one embodiment, but not necessarily in other embodiments. The various instances of the phrase “in one embodiment” or similar phrases in various places in the specification are not necessarily all referring to the same embodiment.

Automatic test equipment (ATE) is often used to test a variety of different electronic components including, but not limited to, integrated circuits (ICs), analog pins, universal serial bus (USB) ports, radio frequency (RF) circuits, differentially paired signal circuitry, and digital pins.

A load board is a circuit board designed to serve as an interface between the automatic test equipment and the device under test (DUT). A load board is also known as an interface board or a DUT board. In some examples, a load board includes a number of components that are used to set up the DUT for correct testing by the ATE, route the test and response signals between the DUT and the ATE, and provide additional test capabilities that the ATE may not be able to provide.

An ideal load board introduces no distortion, noise, delays, nor errors to the testing process of the DUT. This means that an ideal load board is one that does not seem to exist at all, i.e., as if the DUT were directly connected to the ATE. However, all load boards are inherently imperfect and as a result, test results of the DUT may sometimes be skewed or inaccurate.

ATE typically includes one or more pin electronics cards (PECs). A typical PEC is located within the ATE and is used to perform a variety of tests on the DUT.

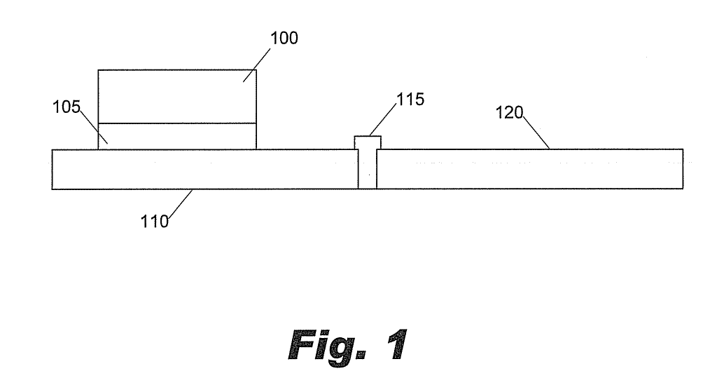

FIG. 1 an illustrative example of an automatic test equipment set up. According to this exemplary embodiment, a DUT (100) is received by a socket (105) which is fixed to a load board (110). The load board (110) is connected to the PEC (120) by a connector (115). The load board may have a plurality of sockets (105) that can receive a number of devices under test (100) of various types. The load board may have additional circuitry to preserve or manipulate signals passing to or from the device under test (100). The pin electronics card (120) can be integrated into a number of control and test systems using variety of connections.

However, a number of disadvantages are associated with the use of PECs to perform the testing of a DUT. For example, signal distortion, bandwidth limitations, signal interference associated with communicating with a DUT that is relatively far away from the PEC can result in testing errors. Moreover, PECs are often costly to manufacture and operate.

Hence, in some examples, a testing system may be provided that is configured to perform one or more tests that are normally performed by the PEC. The testing system may be housed within a chip or IC and located on the load board next to the DUT, for example. Alternatively, the testing system may be configured to be located on the PEC. In this manner, as will be described below, the PEC requirements may be simplified and the testing of various DUTs may be optimized.

In some examples, the exemplary testing system may be configured to test one or more analog devices. Analog pin data often requires high bandwidth to send data back to the ATE. Moreover, analog signals are often distorted or subject to noise injection before they arrive at an analog-to-digital converter (ADC) that is located on the PEC. Driving analog pins is also difficult to do with precision over a long distance.

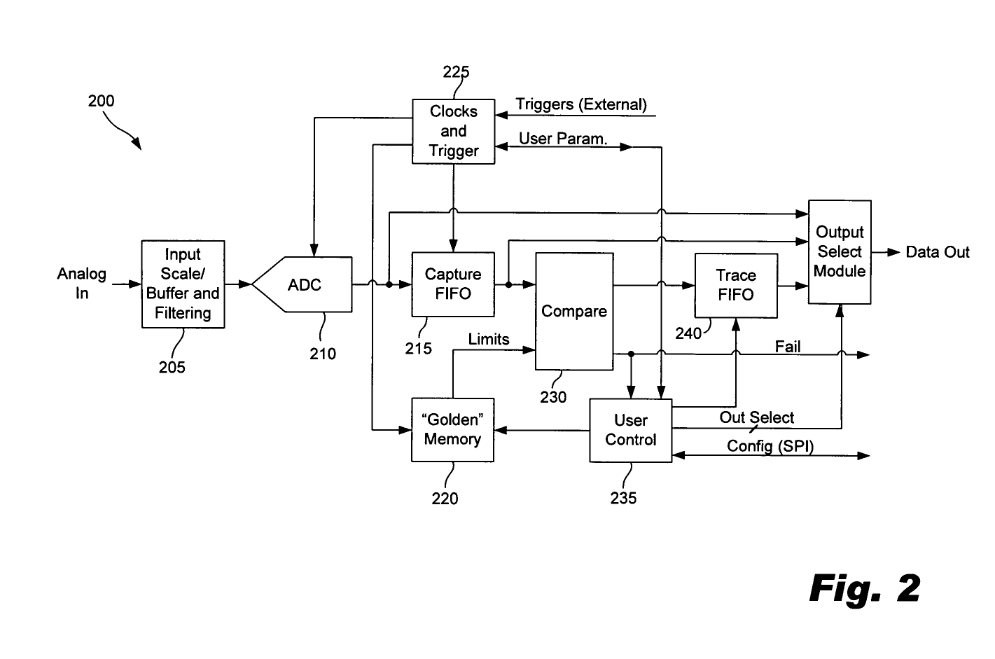

FIG. 2 illustrates an exemplary analog tester (200) that may be used to test an analog DUT. The analog tester (200) may also be referred to as a fast pin recorder. As shown in FIG. 2, the analog tester (200) may include a number of components. It will be recognized that the components shown in FIG. 2 are merely exemplary and that that the number and type of components within the analog tester (200) may vary as best serves a particular application.

In some examples, the analog tester (200) may be configured to measure an analog signal to verify whether the analog signal is within predetermined specifications. For example, as shown in FIG. 2, an analog signal may be introduced into the analog tester (200) through an input scaling/buffering/filtering block (205). The scaling block (205) may be used to scale the analog input signal down to a level that can be processed by the analog tester (200) or to perform other initial signal conditioning.

According to one exemplary embodiment, an analog-to-digital converter (210) receives the scaled and centered signal from the input scaling/buffering/filtering block (205). The analog-to-digital converter (210) converts the analog signal into digital data which is passed to a First In First Out (FIFO) memory buffer (215). According to one exemplary embodiment, the analog-to-digital converter (210) may operate at frequencies above 200 million digital words per second.

A clock and trigger module (225) receives inputs from external triggers and other user supplied parameters. The clock and trigger module (255) connects to a variety of modules to control and synchronize their operation. For example, in FIG. 2 the clock and trigger module (225) connects to the analog-to-digital converter (210), a golden memory (220), and the capture FIFO memory module (215).

The golden memory (220) contains information define various standards or desired signal characteristics against which the signals received from the device under test (100, FIG. 1) are compared. Instead of sending the entire data stream back to the PEC for processing, the analog tester (200) checks the DUT data against a “golden” standard or known good waveform contained within the golden memory module (220). By way of example and not limitation, the golden memory may contain a maximum value and a corresponding minimum value which define a range within which the signal is expected to fall. The golden memory can also contain an ideal value, with a range of acceptance above and below the ideal value. In more sophisticated schemes, the golden memory may contain a signal profile, frequency characteristics, jitter requirements, percentage of mean, maximum deviation, or other parameters which are desired to be measured and compared.

When the capture FIFO memory (215) receives the appropriate trigger or clock signal from the trigger/clock module (225) it passes the portion of the DUT signal received from the analog to digital converter (210) to a compare module (230). The golden memory (220) also passes data which comprises the standard for the given signal to the compare module (230). The compare module (230) mathematically compares the golden standard received from the golden memory module (220) with the DUT signal received from the FIFO memory (215). The results of the comparison are passed to a trace memory (240). According to one exemplary embodiment, the compare module (230) may simply output a “fail” signal or a “pass” signal. In another exemplary embodiment, the compare module (230) may output, in addition to other signals, a mathematical representation that describes the reason for failure or other characteristics of the signal received from the capture FIFO (215). For example, the compare module (230) could take a mathematical difference between the ideal signal received from the golden memory module (220) and the signal received from the capture memory (215).

The actions within the analog tester (200) may be controlled through a user control module (235) which receives user information through an interface. The interface may comprise any number of means for an external control entity (not shown) to communicate with the user control module (235). According to one exemplary embodiment, the user interface is a serial peripheral interface bus. The user control module (235) passes the golden standard data to the golden memory module (220). The user control module (235) also passes controlling information to an output select module (245) which determines which data is output from the analog tester (200). The user control module (235) also passes information to the trace memory (240) or other modules within the analog tester (200).

A trace FIFO memory (240) captures the output of the compare module (230). By accessing the trace FIFO memory (240) through the user control module (235) data from testing performed by the analog tester (200) downloaded and analyzed. For example, the trace memory (240) may store a failure flag which designates that a particular signal failed to meet the standard provided by the golden memory (220). The trace memory (240) may also store data received just prior and just after a failed event. By capturing data surrounding a failed event, the reason for the failure can be more precisely and efficiently determined by testing personnel.

The output select module (245) allows the user to select a variety of options for outputting data from various stages within the analog tester (200). According to one exemplary embodiment, the output select module (245) can extract data immediately after the analog-to-digital conversion or at a location between the capture memory (215) and the compare module (230). Additionally, the output select module (245) can be configured to output the data contained within the trace memory (240).

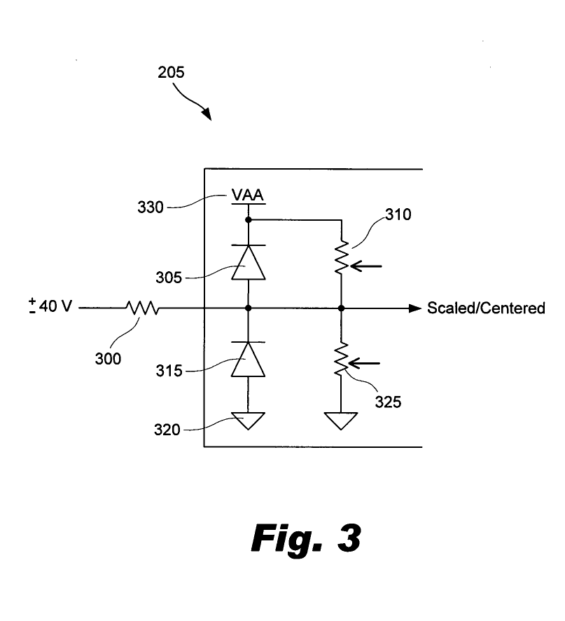

The front end scaling block (205) may include a variety of components in various combinations to appropriately manipulate the analog signal prior to its digital conversion. For example, FIG. 3 illustrates an exemplary front end scaling block (205) that includes an external resistor (300), a plurality of diodes (305, 315), a number of programmable resistors (310, 325), and a number of grounding connections. According to one exemplary embodiment, the external resistor (300) serves to scale the absolute magnitude of the received signal, while the diodes (305, 315) and precision programmable resistors (310, 325) serve to center the signal about a desired mean. An analog voltage supply (330) can be used during the centering operation. However, it will be recognized that the scaling block (205) may additionally or alternatively include other components as may serve a particular application. For example, the external resistor (300) could be an internal programmable resistor. Various other schemes could alternatively be used for scaling, adjusting the mean, filtering, or otherwise conditioning the input signal.

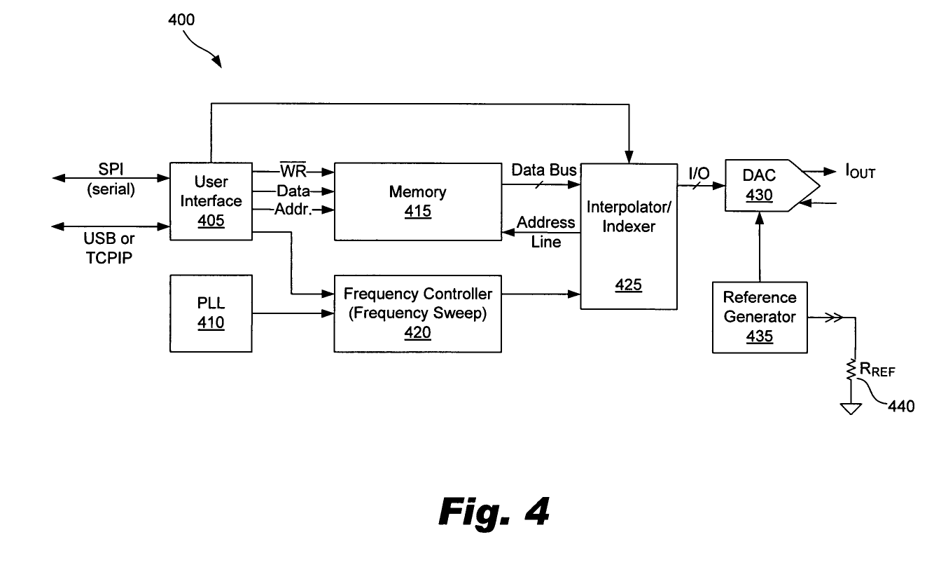

In some examples, an arbitrary waveform generator (AWG) could be included on a load board (110; FIG. 1) separately or in conjunction with an analog tester (200). The arbitrary waveform generator (AWG) is configured to drive analog pin electronics. The use of this AWG circuitry next to the DUT, including placement on the load board can be a primary advantage to using this invention. An exemplary AWG (400) is shown in FIG. 4. The AWG (400) can be triggered externally to start driving an output according to a waveform programmed into internal (or external) chip memory. As shown in FIG. 4, one exemplary embodiment of an arbitrary waveform generator (400) may include a user interface (405), a phase lock loop (410), a memory module (415), a frequency controller (420), and interpolator or indexer (425), a digital-to-analog converter (430), and reference generator (335). Using these components, the arbitrary waveform generator (400) can be configured to synthesize high frequency waveforms, frequency sweeps, as well as other waveforms.

The user interface module (405) can connect to an external control device (not shown) to receive instructions through an SPI port, USB port, a TCP/IP interface, or other interface. The user interface module (405) connects to the memory module (415) to transfer instructions that describe the waveform that is desired to be generated. According to one exemplary embodiment, the user interface (405) connects to the memory module (115) using write, data, and address lines. The memory module (415) may hold point-to-point data as well as instruction bits (e.g., time between sample points, etc.). By way of example and not limitation, if a linear ramp function is desired to be generated, the user interface (405) may pass to the memory module (415) a start level, an end level, and the number of samples or other timing is to occur between the start and end levels. The memory module (415) may provide data to the interpolator (425) at less than the clock rate, which could help time the writes to the memory contained within the interpolator module (425) on odd cycles. The user interface (405) additionally connects to the interpolator module (425), and the frequency controller (420). The phase lock loop module (410) provides a precise reference frequency to the frequency control module (420). According to one exemplary embodiment, the phase lock loop module (410) may include an external crystal or other frequency reference.

The interpolator module (425) outputs a digital representation of the desired waveform which is received by the digital-to-analog converter (430). A reference generator (435) may also be connected to the digital-to-analog converter (430). The reference generator (435) may be attached to ground through a reference resistor (440). The reference resistor (440) may have a fixed value or be a programmable precision resistor. Additionally, the reference resistor (440) may be an internal or external to the arbitrary waveform generator (400). The reference generator (435) provides input to the digital-to-analog converter (430) which determines the full-scale range of the digital-to-analog conversion and the resulting analog output waveform.

In some examples, one or more of the components of the fast pin recorder/analog tester (200) and AWG (400) may be included within a single chip. For example, the analog tester components shown in FIG. 2 may all be included within a single chip and the AWG components shown in FIG. 4 may be included within a single chip. Alternatively, all of the analog tester and AWG components are included within a single chip. The analog tester chip(s) (200, 400) described above may be located on the load board next to the DUT. Alternatively, the analog tester chip(s) may be located on the PEC or at any other suitable location.

Advantages of the analog tester chip(s) (200, 400) include, but are not limited to, improved measurement quality, reduced test time, higher test accuracy, lower system cost, and ease of programming.

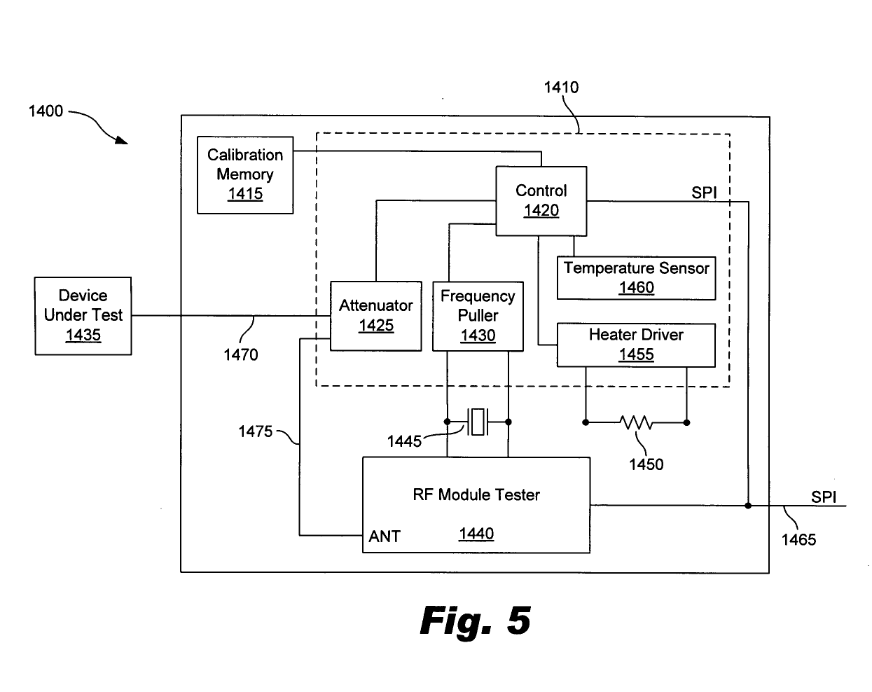

FIG. 5 shows a radio frequency test unit (1400) that is designed to provide a cost-effective method for testing radio frequency reception or computation chips (1435). According to one exemplary embodiment, the radio frequency test unit (1400) is comprised of an RF module tester (1440), a custom chip (1410), and a calibration memory (1415). The RF module tester (1440) can be an off-the-shelf component that is preconfigured to communicate with the device under test (1435). In one exemplary embodiment, the RF module tester (1440) can be a well-characterized off-the-shelf a unit. The RF module (1440) connects to an external crystal (1445) which serves as a frequency reference. A heater (1450) provides temperature stabilization for more accurate and repeatable operation of the RF module tester (1440). The RF module tester (1440) is configured to communicate through an SPI port (1465) and output a signal on an antenna line (1475).

The custom chip (1410) may be comprised of a control module (1420), a temperature sensor (1460), a heater driver (1455), a frequency puller (1430), and an attenuator (1425). The control module (1420) is also connected to the SPI control port (1465). Various control parameters are passed from the control entity (not shown) via the SPI port (1465) to the control module (1420). The control module (1420) accepts information generated by the temperature sensor (1460) and uses that information to control the heater driver (1455). The heater driver (1455) supplies in the desired current and voltage to the heater element (1450). The combination of the heater element (1450), heater driver (1455), and temperature sensor (1460) comprise a close looped temperature control that stabilizes the temperature environment within the RF frequency test unit (1400). The frequency puller (1430) modifies the frequency at which the external crystal (1445) operates by introducing various electronic components (such as capacitance) into the frequency circuit. According to one exemplary embodiment, the frequency puller (1430) modifies the frequency over a range from about plus and minus 20 parts per million from the absolute center of the frequency band.

The attenuator module (1425) accepts the input from the antenna line (1475) and modifies the amplitude of the signal carried on the antenna line (1475) according to control parameters received from the control module (1420). The attenuator module (1425) outputs the resulting signal over an output line (1470) to the device under test (1435). In this way, the device under test (1435) receives an electrical signal that simulates the output of the radio frequency antenna. The frequency modification and the attenuation of the output signal tests the robustness of the device under test (1435). By way of example of a limitation, attenuation could simulate the effect of the receipt of a weaker signal by an antenna. Frequency shifts of the received signal could simulate less than optimal transmitting parts or other non-ideal environmental conditions.

The preceding description has been presented only to illustrate and describe embodiments and examples of the principles described. This description is not intended to be exhaustive or to limit these principles to any precise form disclosed. Many modifications and variations are possible in light of the above teaching.

What is claimed is:

1. A load board based test circuit comprising:
a control module, said control module being configured to receive user input over a user interface;
a testing interface, said testing interface making a connection between said load board based test circuit and a device under test;
a memory, said memory being configured to hold calibration values, test parameters, or test results; and
a means for manipulating a test signal.

2. The test circuit of claim 1, further comprising a means for generating a testing signal.

3. The test circuit of claim 2, wherein said test circuit is contained within a single integrated circuit and mounted to a load board.

4. The test circuit of claim 2, wherein said means for manipulating a test signal comprises a digital-to-analog converter and wherein said memory contains digital data defining said test signal, said memory being in communication with said digital-to-analog converter, said digital-to-analog converter receiving said digital data and outputting an analog waveform.

5. The test circuit of claim 4, wherein an interpolator is interposed between said digital-to-analog converter and said memory; said memory containing only a subset of digital data used to create said test signal; said interpolator receiving said subset of digital data and adding additional digital data to said subset of said digital data to create a digital test signal, said digital-to-analog converter receiving said digital test signal and converting said digital test signal into an analog waveform.

6. The test circuit of claim 5, wherein said interpolator is in communication with a frequency controller, said frequency controller providing timing signals to said interpolator.

7. The test circuit of claim 6, wherein said test circuit is externally triggerable and reprogrammable.

8. The test circuit of claim 7, wherein said interpolator enables the generation of a high order digital waveform from a subset of said digital data.

9. The test circuit of claim 6, wherein said frequency controller is further configured to drive said interpolator and said digital-to-analog converter over a range of frequencies such that a frequency sweep analog waveform is produced.

10. The test circuit of claim 2, wherein said means for generating a test signal comprises radio frequency module tester.

11. The test circuit of claim 10, wherein said means for manipulating said test signal comprises a frequency puller; said frequency puller being configured to change a reference frequency generated by an external crystal; said radio frequency module tester being configured to receive said reference frequency.

12. The test circuit of claim 11, wherein said means for manipulating said test signal further comprises an attenuator, said attenuator being configured to attenuate at least portion of said test signal, said test signal being provided to a device under test.

13. The test circuit of claim 12, further comprising a heater, a temperature sensor, and drive heater circuitry, said drive heater circuitry monitoring said temperature sensor and altering power supplied to said heater such that a substantially constant operating temperature is maintained through a testing period.

14. The test circuit of claim 13, wherein said attenuator, said frequency puller, said heater driver, said drive heater circuitry, and said control module are contained within a single chip, said single chip being configured to modify the performance of said radio frequency module tester.

15. The test circuit of claim 1, wherein said means for manipulating a test signal comprises an analog-to-digital converter, said analog-to-digital converter being configured to receive said test signal from a device under test, said analog-to-digital converter being further configured to digitally sample said test signal and output a digital representation of said test signal.

16. The test circuit of claim 15, further comprising a capture memory, said capture memory being configured to receive said digital representation of said test signal.

17. The test circuit of claim 16, further comprising a golden memory, said golden memory being configured to contain a standard against which said digital representation of said test signal is compared.

18. The test circuit of claim 17, further comprising a compare module and a trace memory, said compare module being configured perform a comparison between said standard and said digital representation of said test signal; said compare module being further configured to output a result of said comparison to said trace memory.

19. The test circuit of claim 18, wherein said result comprises statistical measures of deviations between said standard and said digital representation of said test signal.

20. The test circuit of claim 18, further comprising an output select module, said output select module being in communication with said control module; said output select module being configured to allow a user to select data for output from data generated by said test circuit.

21. The test circuit of claim 20, wherein said test circuit configured to be externally triggered and reprogrammed during operation.

22. The test circuit of claim 15, further comprising a front end scaler, said front end scaler being interposed between said test signal and said analog-to-digital converter; said front end scaler being configured to modify the amplitude and mean of said test signal.

23. The test circuit of claim 22, wherein said test circuit is contained within a single integrated circuit and mounted on a load board.
